(19) United States
(12) Patent Application Publication
(10) Pub. No.: US 2017/0115334 A1
(43) Pub. Date: Apr. 27, 2017

(54) Testing Method and Apparatus

(71) Applicant: VECTA PTY LTD, Brisbane (AU)

(72) Inventor: Michael John Symes, Chandler (AU)

(21) Appl. No.: 15/301,716

(22) PCT Filed: Apr. 2, 2015
(86) PCT No.: PCT/AU2015/050151

§ 371 Date: Oct. 3, 2016

(30) Foreign Application Priority Data
Apr. 3, 2014 (AU) 2014901205

(51) Int. Cl. G01R 29/10; H01Q 1/24; H04B 17/16; G01M 7/02; H04B 17/10

(52) U.S. Cl. CPC G01R 29/105; G01M 7/022; H04B 17/102; H04B 17/16; H01Q 1/24

(57) ABSTRACT

An antenna testing apparatus including a transportable container having a testing chamber that receives an antenna or antenna assembly to be tested in use and an instrument room containing test equipment for use in testing the antenna or antenna assembly.

### BACKGROUND OF THE INVENTION

The present invention relates to a method and apparatus for testing an antenna or antenna assembly and in one particular example to an antenna sector assembly for use at a mobile telecommunications network base station site.

### DESCRIPTION OF THE PRIOR ART

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

In the mobile communications industry, a base station is an installation that operates so to transmit and receive signals from telecommunication devices such as mobile phones or the like. Base stations typically radiate transmit and receive wireless signals through antennas. One example of an antenna is a sector antenna, which is a type of passive, directional antenna having a sector shaped radiation pattern. Typically a number of such antennas are provided at a base station to allow a particular field of coverage. An antenna assembly typically includes one or more sector antennas as well as one or more pieces of base station transmission equipment (commonly known as remote radio heads (RRHs) or remote radio units (RRUs)), as well as jumper cables and possibly filters or other radio frequency (RF) components. Another permutation is that the antenna itself contains base station transmission electronics inside it, a configuration commonly known as an Active Antenna.

A known problem with such antennas and associated transmission equipment, is that they are delicate equipment and issues often arise during or after installation on a base station tower or roof-top. Issues can take many forms, including physical problems such as loose hardware, cables, connections or the like, as well as electrical problems arising for example through interference with local equipment, poor quality of manufacture, materials, or the like.

In general, there is no simple mechanism for testing antenna assemblies and telecommunications companies installing the antenna assemblies rely on these functioning correctly as supplied by the supplier. As a result, problems are often only identified once antenna assemblies have been installed at a site. This raises a number of difficulties. For example, it can be challenging to identify which particular component of the antenna or antenna assembly is causing problems and what the particular problems are, often because of the skill levels available at the installation site. Additionally, replacement or repair of the antenna or RF components in the antenna assembly can prove expensive, once the equipment is mounted in place on a tower or building roof-top.

### SUMMARY OF THE PRESENT INVENTION

In one broad form the present invention seeks to provide an antenna testing apparatus including a transportable container having:
a) a testing chamber that receives an antenna or antenna assembly to be tested in use; and,
b) an instrument room containing test equipment for use in testing the antenna or antenna assembly.

Typically the testing chamber is an anechoic chamber.

Typically the testing chamber is enclosed and the instrument room is provided outside of the enclosed testing chamber.

Typically the testing chamber and instrument room are interconnected by a door, the door including absorber material mounted thereon.

Typically the testing chamber includes a metal floor, walls & ceiling and an absorber material fitted to the walls, floor and ceiling, with the absorber being used for absorbing RF signals.

Typically the testing chamber includes vibration mountings, the antenna or antenna assembly being provided on the vibration mountings to allow the antenna or antenna assembly to be vibrated during testing.

Typically a surface the antenna faces is angled relative to the antenna so that incident antenna radiation is not directly reflected back towards the antenna or antenna assembly.

Typically the surface is at least one of:
a) a ceiling that is sloped at an angle of about 3-5°; and,
b) an absorber mounted to the ceiling and sloped at an angle of about 3-5°.

Typically the apparatus includes a processing system for controlling at least one of:
a) the testing equipment;
b) host equipment;
c) the testing chamber;
d) vibration mountings; and,
e) a linear motion system.

Typically the processing system communicates with host equipment coupled to the antenna or antenna assembly, to cause the host equipment to control the antenna.

Typically when testing antennas, the testing chamber includes at least one test probe antenna that transmits RF signals to or receives RF signals emitted by the antenna or antenna assembly during testing.

Typically when testing antennas, the testing chamber includes linear motion system to allow for antenna radiation pattern measurements to be performed.

Typically when testing antennas, the apparatus includes:
a) an Antenna Interface Standards Group controller (AISG); and,
b) a vector network analyzer.

Typically when testing antennas, the instrument room contains, at least one of:
a) an Antenna Interface Standards Group controller;
b) a vector network analyser; and,
c) a processing system.

Typically when testing antenna assemblies, the apparatus includes:
a) a test mobile device for receiving signals generated by the test probe antenna;
b) a processing system for analysing signals received by test mobile device.

Typically the test mobile is coupled to a test probe antenna via circuitry including at least one of:
a) one or more variable attenuators; and,
b) a diplexing system.

Typically the circuitry is controlled to simulate a range of different conditions.

Typically the host equipment includes at least one of:
a) a Radio Network Controller (RNC);
b) an Operations Support System (OSS); and,
c) a Base Band Unit (BBU) of a host.

Typically when testing antenna assemblies, the testing chamber includes at least one interference antenna that generates interference signals during testing.

An antenna testing method including:
a) providing the antenna or antenna assembly in a testing chamber; and,
b) testing the antenna or antenna assembly by:
   i) having the antenna generate RF signals; and,
   ii) monitoring the generated RF signals.

Typically the method includes using host equipment to cause the antenna or antenna assembly to generate RF signals.

Typically at least some tests are performed outside of the testing chamber.

Typically the method includes performing a visual test to identify at least one of:
a) correct mechanical configuration and connections including grounding;
b) weatherproofing & required labels are in place;
c) loose hardware, corrosion & transport damage.

Typically when testing antennas, the method includes performing antenna test to check at least one of:
a) antenna sidelobe level;
b) elevation beamwidth;
c) correct remote electrical tilt pointing angle; and,
d) measurement of dynamic transmitted PIM.

Typically when testing antenna assemblies, the method includes controlling the testing equipment to generate interference in the testing chamber.

Typically when testing antenna assemblies, the method includes performing at least one of the following tests:
a) visual;
b) digital shelf/Base Band Unit functionality;
c) power supply functionality;
d) Small form factor pluggable (SFP) and Common Public Radio Interface (CPRI)/Open Base Station Architecture Initiative (OBSAI) link via an Operations Support System (OSS)/Local Management Terminal (LMT);
e) radio tests via the Operations Support System (OSS)/Local Management Terminal (LMT);
f) radio tests via the Operations Support System (OSS)/Local Management Terminal (LMT) under dynamic vibration conditions;
g) antenna; and,
h) mobile device

Typically when testing antenna assemblies, the method includes performing a digital shelf/Base Band Unit (BBU) functionality test to at least one of:
a) check correct circuit breaker operation;
b) check correct operation via an Operations Support System (OSS)/Local Management Terminal (LMT); and,
c) check for Base Band Unit (BBU) alarms.

Typically when testing antenna assemblies, the method includes performing a power supply functionality test to check at least one of:
a) voltage parameters;
b) current parameters; and,
c) alarms.

Typically when testing antenna assemblies, the method includes performing a Small form factor pluggable and Common Public Radio Interface (CPRI)/Open Base Station Architecture Initiative (OBSAI) link check via an Operations Support System (OSS)/Local Management Terminal (LMT) test to check at least one of:
a) Small form factor pluggable parameters including at least one of:
   i) temperature;
   ii) optical transmit & receive power;
   iii) manufacturer; and,
   iv) status;
b) Common Public Radio Interface (CPRI)/Open Base Station Architecture Initiative (OBSAI) link parameters including at least one of:
   i) bit error rate;
   ii) delay; and,
   iii) status.

Typically when testing antenna assemblies, the method includes performing radio tests via an Operations Support System (OSS)/Local Management Terminal (LMT) under dynamic vibration conditions to check at least one of:
a) voltage;
b) current;
c) return loss;
d) general alarm status;
e) Antenna Interface Standards Group alarms and Remote Electrical Tilt setting;
f) performance indicators such as:
   i) downlink power;
   ii) committed data rate for voice;
   iii) committed data rate for data;
   iv) radio resource control success;
   v) Remote Azimuth Beamwidth Establishment Success Rate;
   vi) Call Set-up Success Rate;
   vii) uplink Received Signal Strength Indicator/Received Total Wideband Power;
   viii) Erlangs;
   ix) downlink and uplink throughput.

Typically when testing antenna assemblies, the method includes performing antenna test to check immunity to interference under dynamic vibration conditions.

Typically when testing antenna assemblies, the method includes performing mobile device tests to check at least one of:
a) Universal Mobile Telecommunications System Absolute Radio Frequency Channel Number;
b) Radio Resource Control state;
c) transmission power;
d) Received Signal Code Power;
e) Resistor Inductor Capacitor uplink/downlink throughput;
f) Channel Power;
g) Block Error Rate;
h) Speech Mean Opinion Score; and,
i) Data throughput.

### BRIEF DESCRIPTION OF THE DRAWINGS

An example of the present invention will now be described with reference to the accompanying drawings, in which:

FIG. 1A is a schematic perspective view of a mobile testing facility;

FIG. 1B is a schematic perspective view of a mobile testing facility of FIG. 1A in use;

FIG. 1C is a schematic perspective diagram of the functionality of the mobile testing facility;

FIG. 1D is a schematic perspective view of an anechoic test chamber;

FIG. 1E is a schematic diagram of a first example of testing configuration for testing antenna assemblies;

FIG. 1F is a schematic diagram of a second example of a testing configuration for testing antennas; and,

FIG. 2 is a flowchart of an example of testing protocol.

### DETAILED DESCRIPTION OF THE PREFERRED EMBODIMENTS

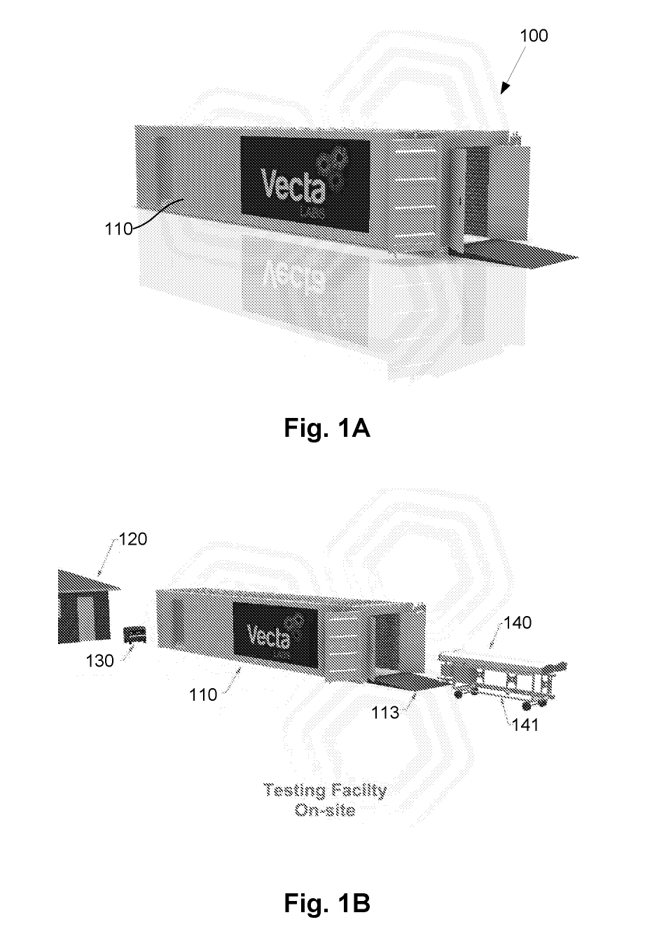

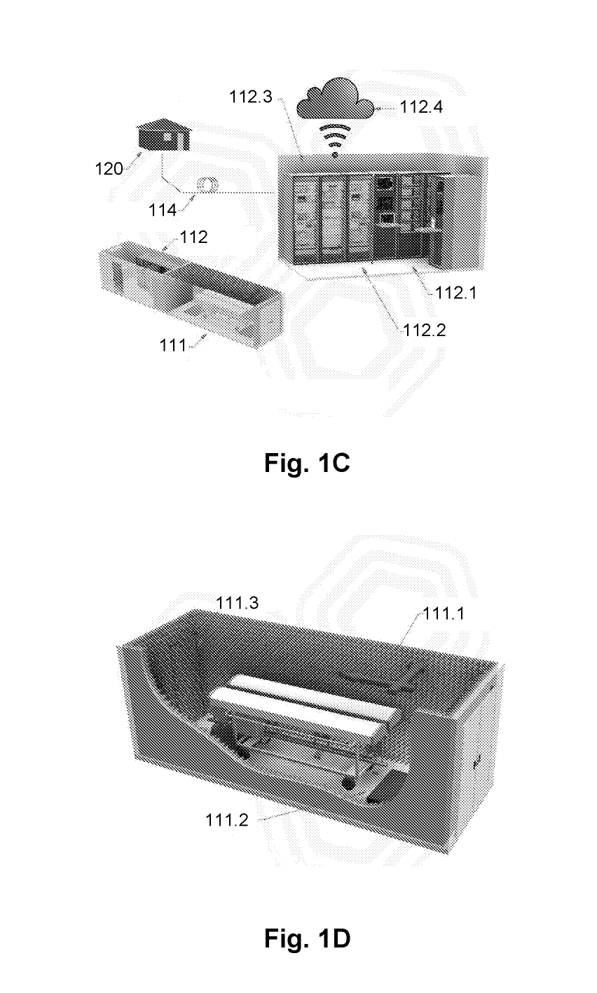

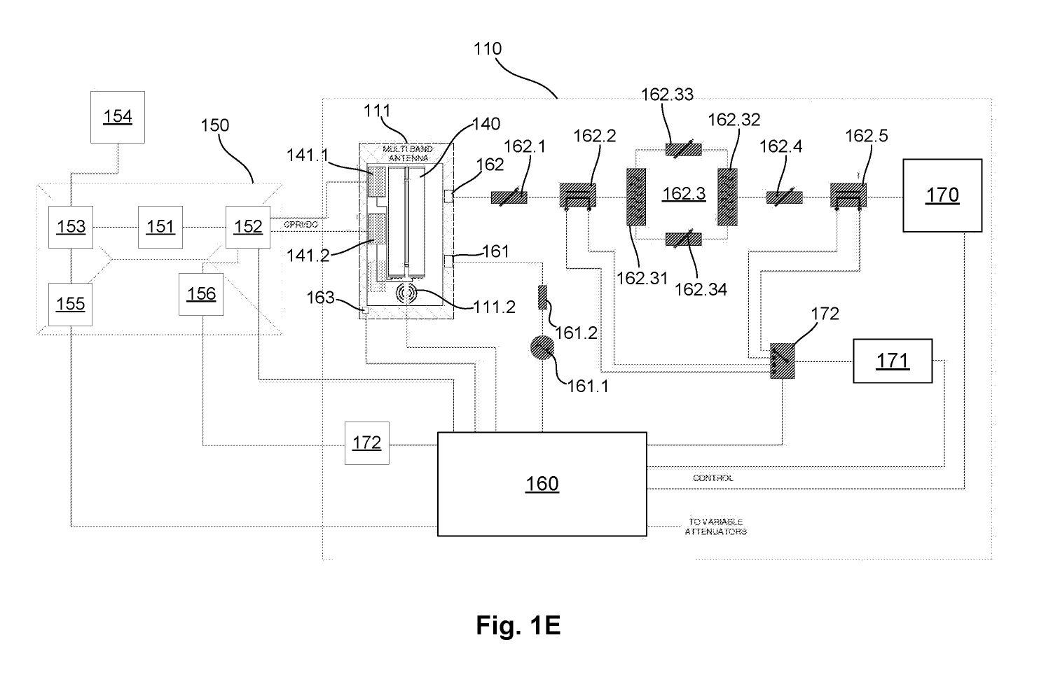

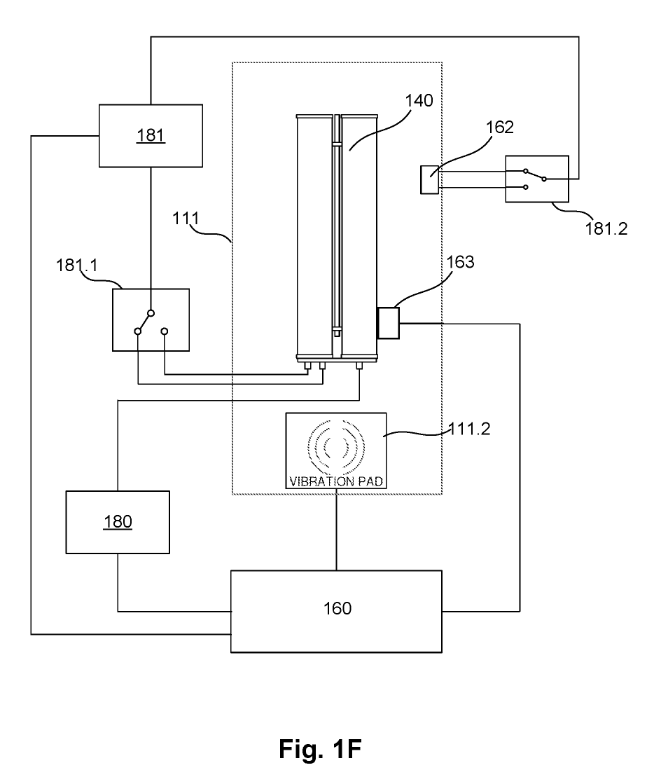

An example of a testing facility for testing sector or other similar telecommunications antennas and antenna assemblies will now be described with reference to FIGS. 1A to 1F.

For the purpose of clarity, the following description will use the term “antenna” to refer collectively to sector or other similar telecommunications antennas, as well as antenna assemblies, and use of the term antenna is not intended to be limited to single antennas.

In this example, the antenna testing apparatus includes a transportable container 110 including a testing chamber 111 that receives an antenna, including an antenna or antenna assembly, to be tested and an instrument room 112 containing test equipment for use in testing the antenna. In use, the antenna 140 is tested by moving the antenna into the testing chamber 111, and testing the antenna at least in part, by having the antenna generate RF signals and monitoring the generated RF signals, for example using the test equipment.

Accordingly, the above described arrangement provides a mechanism for allowing testing of an antenna to be performed using a portable arrangement, allowing antennas to be tested on-site at a facility or other arrangement, prior to installation.

A number of further features will now be described.

In one example the testing apparatus 100 includes a transportable container 110 having an external form factor similar to that of a shipping container. The use of a shipping container form factor is particular advantageous as it can contain the equipment needed to perform testing of antennas whilst also allowing for this to be easily transported using existing transportation mechanisms. The transportable container can be divided into separate rooms or chambers that can provide respective functionality. However, the use of a transportable container is not essential and other arrangements could be used.

As shown in FIG. 1B the transportable container can be easily transported to a host building 120, such as a distribution warehouse, data centre or the like, using normal container transportation arrangements. This allows antennas 140 to be tested in a location which is convenient without having to establish any particular facilities on site beyond those contained in the transportable container.

As shown, the transportable container and the testing equipment provided therein, may be powered by a generator 130, which can be transported within the transportable container meaning that the transportable container may be delivered to a site and then immediately used without it requiring a specific onsite facilities. However, this is not essential, and alternatively, an on-site electrical supply could be accessed.

The transportable container may contain a foldout ramp 113 allowing an antenna 140 to be wheeled into the transportable container 110 on a trolley 141, although this is not essential, and other arrangements could be used.

In one example, the testing chamber 111 is an anechoic chamber and includes a metal floor and absorber 111.1 fitted to the walls, floor and ceiling, the absorber being for absorbing or attenuating RF signals. In one particular example, a surface the antenna faces is angled relative to the antenna so that incident antenna radiation is not directly reflected back towards the antenna or antenna assembly, thus minimising errors in the radiation pattern measurement. In one particular example, the surface is a ceiling that is sloped at an angle of about 5°, although it will be appreciated that any suitable arrangement could be used, such as an absorber mounted to the ceiling or the like.

The testing chamber includes vibration mountings 111.2, the antenna being provided on the vibration mountings, to allow the antenna to be vibrated during testing. In use this allows the trolley 141 and antenna 140 to be vibrated to simulate mechanical stresses that may be encountered during or after installation, for example due to wind loading of the antenna towers or the like. It will be appreciated that this allows a full system test under a vibration environment.

An optional door 111.3 can be provided between the testing chamber 111 and instrument room 112, with the door including absorber material mounted thereon in order to maintain the effectiveness of the anechoic chamber when the door is closed.

Additionally, and/or alternatively, the testing chamber 111 can include a one or two axis linear motion system to allow for one or more preferably two axis (elevation and azimuth) antenna pattern measurements to be performed. For example, by moving a test probe antenna relative to the antenna or antenna assembly under test, the near-field antenna radiation pattern can be measured. Using algorithms in the public domain, the far-field radiation pattern can be simulated in the control system 160. It will be appreciated that in one example the linear motion system and vibration system can be the same equipment, but this is not essential.

The testing chamber typically includes at least one test probe antenna that transmits RF signals to or receives RF signals emitted by the antenna or antenna assembly during testing. The testing chamber also typically includes at least one interference antenna that generates interference signals during testing, as will be described in more detail below.

The instrument room 112 typically contains testing equipment including test equipment and computers 112.1 mounted in racking cabinets 112.2. The instrument room 112 also typically includes a base station's baseband unit (BBU) and test terminals 112.3 as well as the communications facilities 112.4 allowing data to be uploaded to remote processing systems for analysis. Thus, in one example, data can be uploaded to the cloud (i.e. remote servers securely connected to the internet) for processing although this is not essential and alternatively local on-site processing can be performed. The BBU or the like are typically connected via a fibre optic link 114 to the host's establishment 120.

Thus, the test equipment typically includes a test mobile and signal analyser for receiving signals generated by the antenna and a processing system for analysing signals received by the test mobile device. Both the test mobile device and signal analyser can be coupled to test probe antenna via circuitry including one or more fixed or variable attenuators, directional couplers and a diplexing system, allowing the circuitry to be controlled to simulate a range of different conditions.

The control system 160 can also be used for controlling the testing equipment, host equipment, the testing chamber including the vibration mountings for the antenna under test and the 2-axis linear motion system for the test probe. In this regard, the processing system can also communicate with the host equipment coupled to the antenna assembly, to cause the host equipment to control the antenna. In this regard, the host equipment 150 typically includes equipment that is adapted to control the operation of antennas and antenna assemblies in normal operation and may be supplied by a vendor of the antenna or antenna assembly, or another third party. In general, in the case of a UMTS (Universal Mobile Telecommunications System) system, the host equipment would include at least one of a Core Network, an RNC (Radio Network Controller), an OSS (Operations Support System) and BBU (Base Band Unit). However, other suitable arrangements can be used for different antenna systems, as will be described in more detail below.

A specific example of a testing configuration for testing antenna assemblies will now be described in more detail with reference to FIG. 1E.

For the purpose of this example, and as will be apparent from the following explanation, a single test channel using a single standard test mobile device is shown. However, it will be appreciated that this is not intended to be limiting and in practice any number of channels could be provided depending on the preferred implementation.

In this example, as shown the host equipment 150 typically includes the RNC 151 which carries out radio resource management, coupled to a BBU/DU (Baseband Unit/Digital Unit) 152 and onto RRUs (Remote Radio Unit) 141.1, 141.2. The RNC 151 is coupled via fibre optic cable to a packet switched core network 153 to an FTP (File Transfer Protocol) server 154. An alternative configuration replaces the packet switched Core Network with a call switched Core Network & removes the FTP server. The host equipment further 150 includes the OSS 155, a source of Radio Access Network KPIs (Key Performance Indicators), which could be any measurable metric of performance, which is coupled to a test and control system 160, which is in the form of a custom configured processing system, such as a suitable computer server arrangement or the like. The control system 160 communicates with the OSS 155 which is coupled to the Core Network 153. The control system 160 is also typically coupled to the BBU 152, which is in turn coupled to the RRUs 141.1, 141.2 in the antenna assembly via a CPRI (Common Public Radio Interface)/OBSAI (Open Base Station Architecture Initiative) link using fibre optic cables, or the like. This allows the antenna assembly to generate RF signals under the control of the Core Network/RNC system. The BBU 152 is also typically coupled to a power system 156, which is coupled to the control system 160 via a digital multi-meter (DMM) 173, allowing the control system 160 to monitor operation of the power supply 156. Alarms from the Power system 156 can also be monitored.

A dynamic test connection is also provided to allow the control system 160, to control the vibration apparatus 111.2 to thereby apply shock and vibration conditions directly to the antenna or antenna assembly under test.

First and second antennas 161, 162 are mounted in the test chamber 111 for interfacing with the antenna 140 via RF signals. In particular, the interference antenna 161 is coupled via a signal generator 161.1 and attenuator 161.2 allowing interference signals to be generated within the test chamber 111. The second antenna is a test probe antenna 162 to allow RF signals to be received from and transmitted to the antenna or antenna assembly under test. An antenna X-Y control 163 is provided coupled to the control system 160, for controlling the 2-axis linear motion mechanism in the test chamber 111, allowing the test probe antenna 162 to be moved in a 2-D plane. The test probe antenna 162 is coupled via an attenuator 162.1, a coupler (CPLR) 162.2 to a diplexer system 162.3 including two diplexers (DPX) 162.31, 162.32 and variable attenuators (UL, DL) 162.33, 162.34, a further attenuator 162.3 and coupler (CPLR) 162.5 to a test mobile device 170. The test mobile device is a standard commercially available device used in testing, as will be appreciated by persons skilled in the art, and is connected to the control system 160. The couplers (CPLR) 162.2, 162.5 are also connected via a four way switch 172 to a signal analyser 171, which is in turn also coupled to the control system 160.

It will be appreciated that this arrangement allows a variety of signals to be transmitted to and received from the antenna 140. The transmitted/received signals can be monitored by the signal analyser, with adjustment of the components, including the variable attenuators being used to control parameters so as to ascertain the quality of the signal transmitted by the antenna. Additionally, interference can be simulated within the chamber.

Accordingly, by suitable operation, this allows a range of different tests to be performed.

In particular, this allows host equipment to be used to cause the antenna or antenna assembly to generate RF signals, while the control system optionally controls the testing equipment to generate interference in the testing chamber.

A specific example of a testing configuration for testing antennas will now be described in more detail with reference to FIG. 1F.

In this example, the apparatus again includes the chamber 111 for receiving an antenna 140. The chamber includes a vibration mounting 111.2 coupled to the control system 160, which would typically be of a similar form to the control system 160 described above with respect to FIG. 1E.

The control system 160 is also coupled to a probe antenna 162, and an associated X-Y control 163 for controlling a 2-axis linear motion mechanism in the test chamber 111, allowing the test probe antenna 162 to be moved in a 2-D plane relative to the antenna.

The controller 160 is also connected to an AISG (Antenna Interface Standards Group) controller 180, which is in turn coupled to an AISG control port on the antenna, allowing AISG baseband signals to be fed to the antenna's AISG control port. Alternatively, AISG signals (modulated on a 2.176 MHz carrier) may be fed onto the Antenna RF ports. AISG signals are used to control the electrical tilt of the beam most commonly in the elevation plane of the antenna, typically between 0 and 10 degrees downtilt in a mobile cell-site.

Equipment such as vector or scalar network analysers 181 are provided, coupled to the probe antenna 162 and the antenna RF ports via respective switches 181.1, 181.2. The controller 160 controls the analyser 181 and switches 181.1, 181.2 allowing signals to be provided to and analysed from respective ports. In this regard, the network analyser 181, controller 160 and AISG controller 180 can be provided in the test equipment room 112, or outside the container 110, depending on the preferred implementation.

The above arrangement allows a number of different tests to be performed including measuring antenna radiation patterns, as well as related parameters such as gain, cross-polar discrimination, sidelobe level, return loss, port to port isolation, as well as measuring passive intermodulation levels.

Each of the above tests requires different connections to the Antenna RF ports, AISG control port and Test Probes, which can be configured by the controller 160, using the switches 181.1, 181.2, or manually by appropriate set-up. For example, to test an antenna radiation pattern, an RF signal is typically supplied by the vector or scalar network analyser 181 to one port of the antenna under test, with the signal being transmitted by the antenna under test. The same RF signal is received by the test probe (at a much lower level), at a position set by the Test Probe X,Y control. The signal level is assessed to the network analyser as a function of position. The radiation pattern for the antenna under test is calculated using the signal level versus position information.

In the case of PIM testing to measure the reflected or transmitted passive intermodulation levels caused by the antenna under test, the test probe antenna 162, network analyser 181 and switches 181.1, 181.2 are removed and replaced with a PIM Test Instrument. The vibration mountings could also be activated so PIM levels of the antenna under test are measured in a vibration environment.

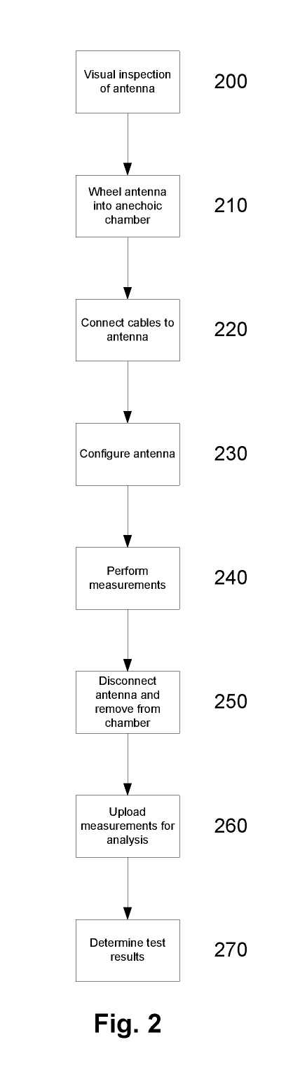

An example testing protocol will now be described with reference to FIG. 2.

In this example, at step 200 visual inspection of the antenna is performed. At step 210 the antenna is provided in the anechoic chamber with cables being connected to the antenna at step 220, allowing the antenna to be coupled via CPRI/OBSAI (fibre optic) and DC interface cables. Configuration of the antenna is performed at step 230, with measurements then being taken automatically by the testing apparatus at step 240. At step 250 the cables are disconnected from the antenna and the antenna will move out of the chamber. At step 260 results of the testing may be sent to the cloud for processing with an indication of the results being displayed at step 270 allowing a pass/fail assessment to be made.

Thus, it will be appreciated that a variety of different tests can be performed, including but not limited to visual, digital shelf/BBU functionality, power supply functionality, SFP & CPRI/OBSAI link via OSS/LMT, radio tests via OSS/LMT, radio tests via OSS/LMT under dynamic vibration conditions, antenna tests and mobile device tests. It should be noted that the visual, digital shelf/BBU functionality, power supply functionality, SFP & CPRI/OBSAI link tests via OSS/LMT can all be carried outside the test chamber 111, for example in a shielded container or inside a second container without shielding. This is because they do not require shielded environment since they do not rely on RF transmit or receive signals.

The visual test is performed to identify that the correct mechanical configuration and connections are in place including grounding, weatherproofing & required labels. In addition checks can be done for loose hardware, corrosion & transport damage.

The digital shelf/BBU functionality test can check correct operation via OSS/LMT and for BBU alarms.

The power supply shelf functionality test to check correct circuit breaker operation, voltage and current parameters or alarms.

The SFP & CPRI/OBSAI link via OSS/LMT test can check SFP parameters such as temperature, optical TX & RX power, manufacturer and status, as well as CPRI/OBSAI link parameters including BER (bit error rate), Delay and status.

The RRU can be accessed via the host's OSS/LMT in order to check parameters such as voltage, return loss, general alarm status, AISG alarms & RET (Remote Electrical Tilt) setting as well as Radio Access KPIs such as DL power, CDR voice, CDR data, RRC Success, RAB Establishment Success Rate, CSSR, UL RSSI/RTWP, Erlangs or DL & UL throughput. Some of the KPIs may change under dynamic vibration conditions. Different KPIs may be of relevance if testing a GSM, CDMA or LTE system, for example.

The antenna test can check at least one of antenna sidelobe level, elevation beamwidth, correct RET pointing angle, measurement of transmitted PIM and noise as well as immunity to interference under dynamic vibration conditions.

The test mobile can check parameters such as UARFCN, RRC state, TXpwr, RSCP, RLC UL/DL throughput, Ec/Io, BLER, Speech MOS and Data throughput. Different parameters may be of relevance if testing a GSM, CDMA or LTE system, for example.

Accordingly, the above described arrangement provides a near field test system for sector antennas or antenna assemblies.

In one example, the system uses an anechoic test chamber with a test probe fitted to 2-axis linear motion system for use when performing radiation pattern measurements. Dynamic vibration testing can be used for checking the presence of PIM (Passive Intermodulation Modulation) or elevated RRU receiver noise floor conditions. A screened instrumentation room is provided to ensure there is no interference with the test equipment. The testing chamber is sealed for RF leakage on 6 sides (including a metallised floor) to ensure that no signal leakage occurs from or to nearby cellular base station or mobile equipment. The testing chamber and testing equipment can be provided in a custom made transportable container, allowing the testing equipment to be provided to a host's facilities as a single unit, thereby allowing for a large degree of flexibility in deployment.

Data collected, analyzed and distributed from by the testing system can be uploaded using cloud computing techniques for remote processing, or alternatively processed locally depending on preferred implementation.

The system can be adapted to provide multiband test capability, to cover cellular frequency bands for example 698-960 MHz and 1710-2690 MHz, though the arrangement could encompass frequencies outside these bands. A high degree of automation allows the system to substantially run in a continuous fashion. Additionally, the modular nature of the arrangement allows for the amount of testing to be adjusted, for example by increasing the number of transportable containers 110 used. This allows a wide range of rollout needs across a network to be accommodated.

The ability to provide consistent measurement and testing, using set testing protocols, equipment and analysis, allows reference standards to be provided for radio performance, allowing telecommunications providers to have a high degree of certainty in terms of operation of their resulting network.

The use of dynamic vibration testing can be used to highlight underlying construction or system assembly issues. For example, with UMTS equipment, this can be used to:
detect transmitted PIM & noise as well as elevated receiver noise floor conditions in the RRU via the RTWP (Received Total Wideband Power) KPI;
detect SFP (Small form factor pluggable) device & CPRI (Common Public Radio Interface)/OBSAI link problems caused by a malfunctioning SFP or poor fibre optic connection;
Identify poor RF jumper construction or installation;
Identify degraded performance in an RF component, jumper, antenna or RRU;
Identify loose hardware or poor construction.

Testing can include, but is not limited to the parameters set out below in Table 1, with this being used to identify the faults outlined in Table 2.

TABLE 1

| Test Type | Possible Test Parameters |
|---|---|
| Visual | Inspect correct mechanical configuration & connections including |
| | grounding |
| | Inspect weatherproofing & required labels are in place |
| | Inspect for corrosion & transport damage |
| Digital Shelf/BBU | Correct configuration file download. Correct operation via |
| Functionality | OSS/LMT. Check no BBU alarms. |
| Power Supply | Voltage, Current. Alarms. Check correct circuit breaker operation. |
| shelf functionality | |
| SFP & | SFP parameters such as temp, optical TX & RX power, |
| CPRI/OBSAI link | manufacturer, status. |
| via OSS/LMT | CPRI/OBSAI link parameters such as BER, delay, status. |
| Radio Tests via | Download configuration file. Setup TX channels. |
| OSS/LMT | Voltage, current, return loss. General alarm status. |
| (under dynamic | AISG alarms & RET setting. |
| vibration | Radio Access Network KPIs such as DL power, CDR voice, CDR |
| conditions) | data, RRC Success, RAB Establishment Success Rate, CSSR, UL |
| | RSSI/RTWP, Erlangs, DL & UL throughput. |
| Antenna | Antenna pattern measurements checking sidelobe level, elevation |
| | beamwidth and correct RET pointing angle |
| | Measurement of dynamic transmitted PIM and noise |
| | Check immunity to interference under dynamic vibration |
| | conditions. |
| Test Mobile | Parameters such as UARFCN, RRC state, TXpwr, RSCP, RLC |
| | UL/DL throughput, Ec/Io, BLER, Speech MOS, data throughput. |

TABLE 2

| Test Type | Typical Faults Detected |
|---|---|
| Visual | Incorrect grounding practices. Incorrect jumper connection. |
| | Incorrect mechanical configuration. Loose hardware. |
| | Missing weatherproofing or required labels. |
| | Corrosion or transport damage |
| Digital Shelf/BBU | Configuration file won't download. |
| Functionality | BBU alarms. |
| Power Supply | Voltage, current out of limit. Circuit breakers operating incorrectly. |
| SFP & | SFP parameters such as temp, optical TX & RX power outside |
| CPRI/OBSAI link | limits. SFP or fibre fault. |
| via OSS/LMT | CPRI/OBSAI link parameters such as BER, delay outside limits. |
| Radio Tests via | Voltage, current, return loss outside limits. |
| OSS/LMT | Incorrect under voltage operation. |
| | RRU alarm |
| | AISG alarms. RET devices not functioning correctly. |
| | Radio Access KPIs outside limits such as DL power, CDR voice, |
| | CDR data, RRC Success, RAB Establishment Success Rate, CSSR, |
| | UL RSSI/RTWP, Erlangs, DL & UL throughput - |
| | RRU incorrect configuration or fault. |
| | RRU, antenna, filter/combiner or jumper faults under vibration. |
| Antenna | Poor antenna sidelobe performance. |
| | Incorrect beam pointing angle or RET malfunction |
| | PIM performance outside limit |
| | Incorrect filter rejection mask |
| Test Mobile | Parameters out of limits such as UARFCN, RRC state, TXpwr, |
| | RSCP, RLC UL/DL throughput, Ec/Io, BLER, speech MOS, data |
| | throughput. |
| | RRU incorrect configuration or fault. |

It will be appreciated that testing could use a combination of manual and automated processes. A manual test process will have a slower cycle time than a fully automated test procedure

Accordingly, the arrangement provides a self-contained, portable, high performance test facility, with one or more units being used at any site to match deployment volumes. The antenna assembly under test links into Core/RNC/BBU/DU equipment at the test facility (location) and uses an industry recognized brand and standard test mobile device.

The arrangement allows a full system test under a vibration environment, from core network through to mobile device, prior to installation of the antenna assembly onto a tower, building roof-top or other structure.

Throughout this specification and claims which follow, unless the context requires otherwise, the word “comprise”, and variations such as “comprises” or “comprising”, will be understood to imply the inclusion of a stated integer or group of integers or steps but not the exclusion of any other integer or group of integers.

Persons skilled in the art will appreciate that numerous variations and modifications will become apparent. All such variations and modifications which become apparent to persons skilled in the art, should be considered to fall within the spirit and scope that the invention broadly appearing before described.

1-32. (canceled)

33. An antenna testing apparatus including a transportable container having:
a) a testing chamber that receives an antenna or antenna assembly to be tested in use; and,
b) an instrument room containing test equipment for use in testing the antenna or antenna assembly.

34. Apparatus according to claim 33, wherein the testing chamber is an anechoic chamber.

35. Apparatus according to claim 33, wherein the testing chamber is enclosed and the instrument room is provided outside of the enclosed testing chamber.

36. Apparatus according to claim 35, wherein the testing chamber and instrument room are interconnected by a door, the door including absorber material mounted thereon.

37. Apparatus according to claim 33, wherein the testing chamber includes at least one of:
a. a metal floor, walls & ceiling and an absorber material fitted to the walls, floor and ceiling, with the absorber being used for absorbing RF signals; and,
b. vibration mountings, the antenna or antenna assembly being provided on the vibration mountings to allow the antenna or antenna assembly to be vibrated during testing.

38. Apparatus according to claim 33, wherein a surface the antenna faces is angled relative to the antenna so that incident antenna radiation is not directly reflected back towards the antenna or antenna assembly.

39. Apparatus according to claim 38, wherein the surface is at least one of:
a. a ceiling that is sloped at an angle of about 3-5°; and,
b. an absorber mounted to the ceiling and sloped at an angle of about 3-5°.

40. Apparatus according to claim 33, wherein the apparatus includes a processing system for controlling at least one of:
a. the testing equipment;
b. host equipment;
c. the testing chamber;
d. vibration mountings; and,
e. a linear motion system.

41. Apparatus according to claim 40, wherein at least one of:
a. the processing system communicates with host equipment coupled to the antenna or antenna assembly, to cause the host equipment to control the antenna; and,
b. the host equipment includes at least one of:
i. a Radio Network Controller (RNC);
ii. an Operations Support System (OSS); and,
iii. a Base Band Unit (BBU) of a host.

42. Apparatus according to claim 33, wherein when testing antennas, the testing chamber includes at least one of:
a. at least one test probe antenna that transmits RF signals to or receives RF signals emitted by the antenna or antenna assembly during testing;
b. a linear motion system to allow for antenna radiation pattern measurements to be performed; and,
c. at least one interference antenna that generates interference signals during testing.

43. Apparatus according to claim 33, wherein when testing antennas, at least one of:
a. the apparatus includes:
i. an Antenna Interface Standards Group controller (AISG); and,
ii. a vector network analyzer; and,
b. the instrument room contains at least one of:
i. an Antenna Interface Standards Group controller;
ii. a vector network analyser; and,
iii. a processing system.

44. Apparatus according to claim 33, wherein when testing antenna assemblies, the apparatus includes:
a. a test mobile device for receiving signals generated by the test probe antenna; and,
b. a processing system for analysing signals received by test mobile device.

45. Apparatus according to claim 44, wherein the test mobile device is coupled to a test probe antenna via circuitry including at least one of:
a. one or more variable attenuators; and,
b. a diplexing system.

46. Apparatus according to claim 45, wherein the circuitry is controlled to simulate a range of different conditions.

47. An antenna testing method including:
a. providing the antenna or antenna assembly in a testing chamber; and,
b. testing the antenna or antenna assembly by:
i. having the antenna generate RF signals; and,
ii. monitoring the generated RF signals.

48. A method according to claim 47, wherein the method includes at least one of:
a. using host equipment to cause the antenna or antenna assembly to generate RF signals;
b. performing at least some tests outside of the testing chamber; and,
c. performing a visual test to identify at least one of:
i. correct mechanical configuration and connections including grounding;
ii. weatherproofing & required labels are in place; and,
iii. loose hardware, corrosion & transport damage.

49. A method according to claim 47, wherein when testing antennas, the method includes performing an antenna test to check at least one of:
a. antenna sidelobe level;
b. elevation beamwidth;
c. correct remote electrical tilt pointing angle; and,
d. measurement of dynamic transmitted PIM.

50. A method according to claim 47, wherein when testing antenna assemblies, the method includes controlling the testing equipment to generate interference in the testing chamber.

51. A method according to claim 47, wherein when testing antenna assemblies, the method includes performing at least one of the following tests:
a. visual;
b. digital shelf/Base Band Unit functionality;
c. power supply functionality;
d. Small form factor pluggable (SFP) and Common Public Radio Interface (CPRI)/Open Base Station Architecture Initiative (OBSAI) link via an Operations Support System (OSS)/Local Management Terminal (LMT);
e. radio tests via the Operations Support System (OSS)/Local Management Terminal (LMT);
f. radio tests via the Operations Support System (OSS)/Local Management Terminal (LMT) under dynamic vibration conditions;
g. antenna; and,
h. mobile device

52. A method according to claim 47, wherein when testing antenna assemblies, the method includes at least one of:
a. performing a digital shelf/Base Band Unit (BBU) functionality test to at least one of:
i. check correct circuit breaker operation;
ii. check correct operation via an Operations Support System (OSS)/Local Management Terminal (LMT); and,
iii. check for Base Band Unit (BBU) alarms.
b. performing a power supply functionality test to check at least one of:
i. voltage parameters;
ii. current parameters; and,
iii. alarms.
c. performing a Small form factor pluggable and Common Public Radio Interface (CPRI)/Open Base Station Architecture Initiative (OBSAI) link check via an Operations Support System (OSS)/Local Management Terminal (LMT) test to check at least one of:
i. Small form factor pluggable parameters including at least one of:
1. temperature;
2. optical transmit & receive power;
3. manufacturer; and,
4. status;
ii. Common Public Radio Interface (CPRI)/Open Base Station Architecture Initiative (OBSAI) link parameters including at least one of:
1. bit error rate;
2. delay; and,
3. status.
d. performing radio tests via an Operations Support System (OSS)/Local Management Terminal (LMT) under dynamic vibration conditions to check at least one of:
i. voltage;
ii. current;
iii. return loss;
iv. general alarm status;
v. Antenna Interface Standards Group alarms and Remote Electrical Tilt setting;
vi. performance indicators such as:
1. downlink power;
2. committed data rate for voice;
3. committed data rate for data;
4. radio resource control success;
5. Remote Azimuth Beamwidth Establishment Success Rate;
6. Call Set-up Success Rate;
7. uplink Received Signal Strength Indicator/Received Total Wideband Power;
8. Erlangs;
9. downlink and uplink throughput.
e. performing an antenna test to check immunity to interference under dynamic vibration conditions.
f. performing mobile device tests to check at least one of:
i. Universal Mobile Telecommunications System Absolute Radio Frequency Channel Number;
ii. Radio Resource Control state;
iii. transmission power;
iv. Received Signal Code Power;
v. Resistor Inductor Capacitor uplink/downlink throughput;
vi. Channel Power;
vii. Block Error Rate;
viii. Speech Mean Opinion Score; and,
ix. Data throughput.
